(19) United States
(12) Patent Application Publication
(10) Pub. No.: US 2026/0371927 A1
(43) Pub. Date: Nov. 19, 2026

(54) THERMOELECTRIC CONJUGATED POLYMERS

(71) Applicant: CAMBRIDGE ENTERPRISE LIMITED., Cambridge (GB)

(72) Inventors: Henning SIRRINGHAUS; Ian JACOBS, Cambridge (GB); Wenjin ZHU, Cambridge (GB)

(21) Appl. No.: 19/515,477

(22) PCT Filed: Sep. 2, 2024
(86) PCT No.: PCT/EP2024/074472

§ 371 Date: Mar. 1, 2026

(30) Foreign Application Priority Data
Sep. 1, 2023 (GB) 2313370.5

(51) Int. Cl. H10N 10/856; C08L 65/00; H10K 85/10

(52) U.S. Cl. CPC H10N 10/856; C08L 65/00; H10K 85/113; H10K 85/151; C08L 2203/20; C08L 2205/025

(57) ABSTRACT

The present invention relates to a semi-crystalline polymeric material, preferably for a thermoelectric device, the material comprising a first conjugated polymer, a second conjugated polymer blended with the first conjugated polymer, and a dopant, wherein the second conjugated polymer has a number average molecular weight which is 25% greater or more than the first conjugated polymer. A method of preparing a semi-crystalline polymeric material, the use of the semi-crystalline polymeric material and a thermometric device comprising the semi-crystalline polymeric material are also described.

### INTRODUCTION

The invention relates to the field of thermoelectric material. Specifically, the invention relates to semi-crystalline polymeric material for use in a thermoelectric device. The use of the semi-crystalline polymeric material as a thermoelectric material and a method of manufacturing the semi-crystalline polymeric material is also described.

### BACKGROUND

Due to their relatively low thermal conductivities and the ability to tune their molecular structure and carrier concentrations, conjugated polymers are being increasingly investigated as thermoelectric materials for operation near ambient temperature¹. However, their thermoelectric performance typically remains inferior to state-of-art inorganic thermoelectrics, such as Bi₂Te₃².

Achieving high performance in thermoelectric materials relies on strategies that increase the electrical conductivity and Seebeck coefficients of the materials while minimising increases in thermal conductivity. This leads to an improved Power Factor (PF), defined according to the equation 1 below, and an improved thermoelectric figure of merit (ZT), defined according to the equation 2. In equations 1 and 2, o is the electrical conductivity, K is thermal conductivity, S is the Seebeck coefficient and T is temperature.

PF=S²σ Equation 1

ZT=S²σT/κ Equation 2

One known approach for enhancing the electrical conductivities, Seebeck coefficients S and power factors involves inducing uniaxial alignment of the polymer chains along the thermoelectric transport direction³. Intrachain transport along the polymer backbone is much faster than interchain transport between polymer chains and as a result the conductivity along the polymer chain alignment direction is generally significantly higher than that perpendicular to the alignment direction or that of polymer films with no chain orientation^{3c,4}. However, this strategy is not always effective at increasing the overall thermoelectric figure of merit, as the enhanced electrical conductivity is often accompanied by an increase in the thermal conductivity along the chain alignment direction.

Further, the semi-crystalline nature of these materials means that the aligned polymer chains form discrete crystalline domains that are separated by well-defined grain boundaries in which the chain ends are located. These grain boundaries can then dominate the performance of the material. For example, in the ribbon phase of Poly[2,5-bis(3-dodecylthiophen-2-yl)thieno[3,2-b]thiophene] (PBTTT), which is one of the most highly ordered semicrystalline conjugated polymers with a microstructure that is reminiscent of that of semicrystalline polyethylene, work using Scanning Kelvin Probe Microscopy (SKPM) has shown that these grain boundaries between ribbons constitute bottlenecks for the overall charge transport⁵.

### SUMMARY OF INVENTION

In an aspect of the invention there is provided a semi-crystalline polymeric material, preferably for a thermoelectric device, the material comprising:
a first conjugated polymer;
a second conjugated polymer blended with the first conjugated polymer; and
a dopant;
wherein the second conjugated polymer has a number average molecular weight which is 25% greater or more than the number average molecular weight than the first conjugated polymer.

In another aspect of the invention there is provided a semi-crystalline polymeric material, preferably for a thermoelectric device, the material comprising:
a first conjugated polymer;
a second conjugated polymer blended with the first conjugated polymer; and
a dopant,
wherein the second conjugated polymer has a number average molecular weight greater than the number average molecular weight of the first conjugated polymer; and
wherein the HOMO energy level of the second conjugated polymer is within 0.1 eV of the HOMO energy level of the first conjugated polymer; or wherein the LUMO energy level of the second conjugated polymer is within 0.1 eV of the LUMO energy level of the first conjugated polymer.

In another aspect of the invention there is provided a semi-crystalline polymeric material, preferably for a thermoelectric device, the material comprising:
a first conjugated polymer;
a second conjugated polymer blended with the first conjugated polymer; and
a dopant,
wherein the second conjugated polymer has a number average molecular weight greater than the number average molecular weight of the first conjugated polymer; and
the first conjugated polymer and the second conjugated polymer form crystalline domains comprising both of said first and second conjugated polymers, and preferably the first conjugated polymer and the second conjugated polymer comprise of, and preferably consist of, the same conjugation system or the same delocalised pi system.

In a further aspect of the invention there is provided a method of preparing a semi-crystalline polymeric material, preferably for a thermoelectric device, the method comprising:
blending a first conjugated polymer with a second conjugated polymer;
depositing the blended polymers on a substrate; and
doping the first and second conjugated polymers with a dopant;
wherein the second conjugated polymer has a number average molecular weight which is 25% greater or more than the number average molecular weight of the first conjugated polymer.

In a further aspect of the invention there is provided a method of preparing a semi-crystalline polymeric material comprising:
separately doping each of a first conjugated polymer and a second conjugated polymer with a dopant;
blending the first doped conjugated polymer with the second doped conjugated polymer; and
depositing the blended polymers on a substrate;
wherein the second conjugated polymer has a number average molecular weight which is 25% greater or more than the number average molecular weight of the first conjugated polymer.

In a further aspect of the invention there is provided a method of preparing a semi-crystalline polymeric material, preferably for a thermoelectric device, the method comprising:
blending a first conjugated polymer with a second conjugated polymer;
depositing the blended polymers on a substrate; and
doping the first and second conjugated polymers with a dopant;
wherein the second conjugated polymer has a number average molecular weight greater than the number average molecular weight of the first conjugated polymer; and
wherein:
   a) the HOMO energy level of the second conjugated polymer is within 0.1 eV of the HOMO energy level of the first conjugated polymer or the LUMO energy level of the second conjugated polymer is within 0.1 eV of the LUMO energy level of the first conjugated polymer; or
   b) the first conjugated polymer and the second conjugated polymer form crystalline domains comprising both of said first and second conjugated polymers, and preferably the first conjugated polymer and the second conjugated polymer comprise of, and preferably consist of, the same conjugation system or the same delocalised pi system.

In a further aspect of the invention there is provided a method of preparing a semi-crystalline polymeric material, preferably for a thermoelectric device, the method comprising:
separately doping each of a first conjugated polymer and a second conjugated polymer with a dopant;
blending the first doped conjugated polymer with the second doped conjugated polymer; and
depositing the blended polymers on a substrate;
wherein the second conjugated polymer has a number average molecular weight greater than the number average molecular weight of the first conjugated polymer; and
wherein:
   a) the HOMO energy level of the second conjugated polymer is within 0.1 eV of the HOMO energy level of the first conjugated polymer or the LUMO energy level of the second conjugated polymer is within 0.1 eV of the LUMO energy level of the first conjugated polymer; or
   b) the first conjugated polymer and the second conjugated polymer form crystalline domains comprising both of said first and second conjugated polymers, and preferably the first conjugated polymer and the second conjugated polymer comprise of, and preferably consist of, the same conjugation system or the same delocalised pi system.

The invention also relates to the use of the semi-crystalline polymeric material of the aspects described above to form a layer on a substrate.

The invention also relates to the use of the semi-crystalline polymeric material of the aspects described above as a thermoelectric material.

The invention also relates to the use of the semi-crystalline polymeric material of the aspects described above to form a layer of a thermoelectric device.

The invention also relates to a layer on a substrate, wherein said layer comprises the semi-crystalline polymeric material of the aspects described above.

The invention also relates to a thermoelectric device comprising the semi-crystalline polymeric material of the aspects described above.

### DEFINITIONS

As used herein the term “semi-crystalline” refers to a material comprising discrete crystalline and amorphous regions. Specifically, a material comprising crystalline domains separated by amorphous domains.

As used herein the term “crystalline domains” refers to an area of order within a polymeric material due to the alignment, or at least partial alignment, of the polymers, i.e. the polymer chains.

As used herein the term “conjugated” refers to polymers that comprise areas or regions of delocalization along their chain axis. For example, polymers comprising a delocalized pi system.

As used herein the term “blended” refers to a combination or mixture of two polymers wherein the two polymers are distributed throughout the mixture, i.e. they are intimately mixed. It will be appreciated that in semi-crystalline polymeric materials comprising a blend of two polymers, the polymeric material comprises crystalline domains that contain both the blended polymers, as opposed to comprising separate or discrete crystalline domains of each polymer.

As used herein the term “dopant” refers to a substance introduced to a polymer for the purpose of modulating its electrical properties.

As used herein the term “HOMO energy level” refers to the energy level of the highest occupied molecular orbital. The difference in HOMO energy levels between two conjugated polymers can be calculated by separately determining the HOMO levels of the polymers by techniques, such as cyclic voltammetry or ultraviolet photoelectron spectroscopy, or other techniques know to a person skilled in the art.

As used herein the term “LUMO energy level” refers to the energy level of the lowest unoccupied molecular orbital. The difference in LUMO energy levels between two conjugated polymers can be calculated by separately determining the LUMO levels of the polymers by techniques, such as cyclic voltammetry or ultraviolet photoelectron spectroscopy combined with measurements of the band gap by optical spectroscopy, or other techniques know to a person skilled in the art.

As used herein the term “average molecular weight” refers to number average molecular weight as determined by gel permeation chromatography unless otherwise stated.

### DETAILED DESCRIPTION OF THE INVENTION

As discussed above, in an aspect of the invention there is provided a semi-crystalline polymeric material, preferably for a thermoelectric device, the material comprising:
a first conjugated polymer;
a second conjugated polymer blended with the first conjugated polymer; and
a dopant;
wherein the second conjugated polymer has a number average molecular weight which is 25% greater or more than the number average molecular weight of the first conjugated polymer.

In general, the present invention proposes a new mechanism for increasing the thermoelectric performance of conjugated polymers through the use of a blend of conjugated polymers having different number average molecular weights. Advantageously, this has been observed to lead to an increase in the electrical conductivity without significantly impacting the Seebeck coefficient and without a proportional increase in thermal conductivity, thereby resulting in an improved thermoelectric figure of merit (ZT).

Without wishing to be bound by theory, it is believed that incorporation of a higher number average molecular weight conjugated polymer with a lower number average molecular weight conjugated polymer results in an increase in the presence of “tie chains”. These tie chains are presumed to connect adjacent crystalline domains and allow charges to cross between the crystalline domains without having to undergo interchain hopping within the disordered domains. It was entirely unexpected that this arrangement would improve the electrical conductivity and Seebeck coefficient of the material, without proportional increases in the thermal conductivity.

Embodiments of the various aspects of the invention are described below. For the avoidance of doubt, it will be appreciated, where appropriate, that any embodiments as described herein in relation to one aspect of the present invention will also apply to the other aspects of the present invention, where appropriate.

### Tie Chains

As mentioned above, the materials of the present invention have advantageously been found to possess beneficial thermoelectric performance. This arises due to the blending of a lower number average molecular weight conjugated polymer and a higher number average molecular weight conjugated polymer. Preferably the first conjugated polymer and the second conjugated polymer form crystalline domains comprising both of said first and second conjugated polymers.

Without wishing to be bound by theory, the improvement in thermoelectric performance is believed to occur due to the higher number average molecular weight conjugated polymer forming tie chains that link discrete crystalline domains. Accordingly, in preferred embodiments of the invention, the semi-crystalline polymeric material comprises discrete crystalline domains and the second conjugated polymer links at least two of the crystalline domains. Evidence of these tie chains is discussed in detail in the experimental section below.

### Alignment of the Polymers

Preferably, the first and second conjugated polymer are preferentially aligned in a single direction. This can be advantageous in improving charge transport along the alignment direction. It may also allow for the charge transport properties to be optimised in the direction of current flow, or in the direction of the temperature gradient, within a thermoelectric device. Accordingly, for thermoelectric devices comprising the semi-crystalline polymeric material herein described, it is preferable that the first and second conjugated polymers are preferentially aligned in the direction of current flow or the direction of a temperature gradient in said device.

### Relationship Between the Two Polymers

It will be appreciated that the second conjugated polymer could be a different polymer to the first conjugated polymer, or that the second conjugated could be the same polymer as the first conjugated polymer, only with a different number average molecular weight.

Preferably the second conjugated polymer is the same as, or is closely related to the first conjugated polymer, i.e. in terms of structure. Using the same or very similar conjugated polymers is advantageous in ensuring that the electrical conductivity is not significantly impacted by the presence of the second conjugated polymer, and the charge carriers can readily “hop” between the chains of both conjugated polymers. In particular, it is believed that utilising two conjugated polymers that have energy levels within a few k_{B}T could avoid significantly impacting the charge transport. However, it will also be appreciated that a slight difference in the conjugated polymers, and therefore their energy levels, could be beneficial in order to provide increases in the Seebeck coefficient.

Accordingly, in preferred embodiments, the HOMO energy level of the second conjugated polymer is within 0.1 eV of the HOMO energy level of the first conjugated polymer. In other preferred embodiments, the LUMO energy level of the second conjugated polymer is within 0.1 eV of the LUMO energy level of the first conjugated polymer. It will be appreciated that by the term “within 0.1 eV”, it refers to the situation where the HOMO/LUMO energy level of second conjugated polymer is less than or equal to 0.1 eV above or 0.1 eV below the HOMO/LUMO energy level first conjugated polymer, i.e. +/−0.1 eV.

Preferably the HOMO energy level of the second conjugated polymer is within 0.05 eV of the HOMO energy level of the first conjugated polymer, such as within 0.02 eV or within 0.01 eV.

Preferably the LUMO energy level of the second conjugated polymer is within 0.05 eV of the LUMO energy level of the first conjugated polymer, such as within 0.02 eV or within 0.01 eV.

It will be appreciated that a closely, but not exactly matched HOMO level, can occur in situation where the second conjugated polymer has a substantially similar backbone structure than the first conjugated polymer. This similarity may also allow the second polymer to be incorporated into the crystalline domains without introducing disorder.

Accordingly, in optional embodiments, the first conjugated polymer and the second conjugated polymer comprise substantially the same polymeric backbone.

Optionally, the first conjugated polymer and the second conjugated polymer comprise of, and preferably consist of, the same conjugation system.

Optionally, the first conjugated polymer and the second conjugated polymer comprise of, and preferably consist of, the same delocalised pi system.

Optionally, the first conjugated polymer and the second conjugated polymer differ only by single-atom substitutions in the polymer repeat unit, preferably whilst the conjugated polymer maintains the same bonding pattern of the polymer backbone. For example, the first conjugated polymer may be PBTTT and the second polymer may be PBSTT. Optionally, the first conjugated polymer and the second conjugated polymer differ only in the attachment of electron-withdrawing or electron-donating groups to the polymer backbone.

Other differences in the first and second conjugated polymers that may be present (in addition to the different number average molecular weight) include different terminal or end groups and different types and/or numbers of side chains. For example, the first conjugated polymer and the second conjugated polymer have different length side chains. In particular, the first conjugated polymer and the second conjugated polymer may have the same (or similar) backbone but a different length side chain. It is believed that the differences that may be tolerated are those that do not significantly change the crystal structure or the energy levels of the polymer backbone. It is thought, however, that it could be advantageous for the second conjugated polymer to be subtly different to the first conjugated polymer so the tie chains act as an energy filter. If charges are forced to travel across a conjugated polymer (i.e. a tie chain) that is at a slightly higher energy then this increases the Seebeck coefficient, i.e. thermoelectric performance is improved.

Optionally, the first conjugated polymer and the second conjugated polymer have the same side chains, or at least the same length side chains.

Optionally, the first conjugated polymer and the second conjugated polymer comprise, preferably consist of, the same repeat unit or the same repeating units.

Optionally, the first conjugated polymer and the second conjugated polymer are the same, except and their number average molecular weights, and possibly except for their terminal groups.

### Molecular Weights

Preferably the number average molecular weight of the second conjugated polymer is 35% greater or more than the number average molecular weight of the first conjugated polymer. For example, 40% greater or more, or 45% greater or more.

Further preferably the number average molecular weight of the second conjugated polymer is 50% greater or more than the number average molecular weight of the first conjugated polymer. For example, 60% greater or more, or 70% greater or more.

Further preferably, the number average molecular weight of the second conjugated polymer is 75% greater or more than the number average molecular weight of the first conjugated polymer. For example, 80% greater or more.

Without wishing to be bound by theory, it is believed that increasing the number average molecular weight (and therefore the length of the polymer chain) of the second conjugated polymer improves the likelihood of the second conjugated polymer becoming associated with two discrete crystalline domains and therefore increase the likelihood of forming a tie chain.

Preferably the number average molecular weight of the second conjugated polymer is 500% greater or less than the number average molecular weight of the first conjugated polymer.

Further preferably the number average molecular weight of the second conjugated polymer is 350% greater or less than the number average molecular weight of the first conjugated polymer.

Further preferably the number average molecular weight of the second conjugated polymer is 250% greater or less than the number average molecular weight of the first conjugated polymer.

In some preferred embodiments, the number average molecular weight of the second conjugated polymer is from 50% to 250% of the number average molecular weight of the first conjugated polymer. Further preferably the number average molecular weight of the second conjugated polymer is from 75% to 150% of the number average molecular weight of the first conjugated polymer.

Preferably the first conjugated polymer has a number average molecular weight of at least 5 KDa. For example, at least 10 kDa or at least 12.5 KDa.

Preferably the first conjugated polymer has a number average molecular weight of at least 15 KDa. For example, at least 20 KDa, at least 25 kDa or at least 30 kDa.

Preferably the first conjugated polymer has a number average molecular weight of less than 60 KDa, such as less than 50 KDa.

Preferably the second conjugated polymer has a number average molecular weight of at least 30 KDa.

Preferably the second conjugated polymer has a number average molecular weight of at least 50 KDa, such as at least 60 KDa.

Preferably the second conjugated polymer has a number average molecular weight of less than 120 KDa, such as less than 100 KDa.

Preferably the first conjugated polymer and/or the second conjugated polymer has a polydispersity index of 2 or less.

Further preferably the first conjugated polymer and/or the second conjugated polymer has a polydispersity index of 1.5 or less. The first conjugated polymer may have a polydispersity index of 1.2 or less.

Advantageously, a low polydispersity may provide a well ordered structure with discrete crystalline domains that can be effectively linked by tie chains

### Relative Composition

As shown in the examples below and FIG. 2, the proportion of the two blended conjugated polymers can have a significant effect on the overall thermoelectric performance. Without wishing to be bound by theory, it is believed that the first conjugated polymer is primarily responsible for forming ordered crystalline domains, while the second conjugated component is primarily responsible for forming the tie chains linking said domains. As result, it is preferable for the first conjugated polymer to be in excess relative to the second conjugated polymer. Accordingly, in preferred embodiments, the molar ratio of the second conjugated polymer in the blend of the first conjugated polymer and the second conjugated polymer is less than 50%. For example less than 40%.

Preferably the molar ratio of the second conjugated polymer in the blend of the first conjugated polymer and second conjugated polymer is less than 30%, such as less than 25% or less than 20%.

Preferably, the molar ratio of the second conjugated polymer in the blend of the first conjugated polymer and the second conjugated polymer is greater than 5%. For example, greater than 7% or greater than 8%.

Further preferably, the molar ratio of the second conjugated polymer in the blend of the first conjugated polymer and the second conjugated polymer is greater than 10%. For example, greater than 12.5% or greater than 15%.

In some embodiments, the molar ratio of the second conjugated polymer in the blend of the first conjugated polymer and the second conjugated polymer is between 5 and 50%, such as between 7.5 and 40%.

Preferably, the molar ratio of the second conjugated polymer in the blend of the first conjugated polymer and the second conjugated polymer is between 10 and 30%, such as between 12.5 and 25%.

### Polymer Structure

Preferably the first conjugated polymer and/or the second conjugated polymer is selected from homopolymers, such as polythiophenes, polyselenophenes, polyfuranes or polythiazoles; donor-donor copolymers, such as polymers comprising thiophene, thienothiophene and/or selenophene units; and/or donor acceptor copolymers, such as polymers comprising diketopyrrolopyrrole units or copolymers comprising thiophene and fluorinated benzothiadiazole.

Preferably the first conjugated polymer and/or the second conjugated polymer comprises a thiophene unit within the polymer backbone.

Preferably the first conjugated polymer and/or the second conjugated polymer is selected from poly(2,5-bis(3-alkylthiophene-2-yl)thieno(3,2-b)thiophene (PBTTT), Poly(3-hexylthiophene) (P3HT) or poly[[2,5-bis(2-octadecyl)-2,3,5,6-tetrahydro-3,6-diketopyrrolo[3,4-c]pyrrole-1,4-diyl]-alt-(2-octylnonyl)-2,1,3-benzotriazole] (DPPBTz).

Preferably the first conjugated polymer and/or the second conjugated polymer is poly(2,5-bis(3-alkylthiophene-2-yl)thieno(3,2-b)thiophene) (PBTTT).

The first conjugated polymer and/or the second conjugated polymer may be poly(2,5-bis(3-alkylselenophen-2-yl)thieno (3,2-b)thiophene (PBSTT).

For example, the first conjugated polymer may be poly(2,5-bis(3-alkylthiophene-2-yl)thieno(3,2-b)thiophene) (PBTTT) and the second conjugated polymer may be poly(2,5-bis (3-alkylselenophen-2-yl)thieno (3,2-b)thiophene (PBSTT), or vice versa.

Preferably the semi-crystalline polymeric material comprises ribbons of aligned polymers.

Preferably the semi-crystalline polymeric material comprises discrete crystalline domains and the polymeric chains of the first conjugated polymer adopt a substantially straight conformation within the crystalline domains. Advantageously, this “chain extended” structure optimises charge transport through the crystalline domains. It will be appreciated that the straight conformation can be achieved by optimising the number average molecular weight of the first conjugated polymer.

Preferably the dopant is selected from a neutral molecular dopant, an ionic dopant, a closed shell ion introduced by an ion exchange process, a dopant introducing electrophilic or nucleophilic attack, or a dopant inducing proton transfer.

Preferably the dopant is an ion-exchange dopant.

Further preferably the dopant comprises FeCl₃ and/or 1-Butyl-1-methylpyrrolidinium bis(trifluoromethylsulfonyl)imide (BMP-TFSI).

Preferably the semi-crystalline polymeric material comprises a molar doping ratio of 0.01 to 2 charge carriers per monomer. Further preferably a molar doping ratio 0.1 to 1 charge carriers per monomer.

### Methods of Preparing the Semi-Crystalline Polymeric Material

As described in the aspects above, the method of the present invention can either comprise blending two conjugated polymers and then doping the blended conjugated polymers, or can involve doping unblended conjugated polymers and then blending the doped conjugated polymers together. Preferably doping is conducted after blending as the conjugated polymers are more soluble prior to doping leading to an improved blending step.

Preferably depositing the blended conjugated polymers further comprises aligning the blended conjugated polymers. Advantageously, aligning the conjugated polymers can lead to improved charge transport through the material, particularly along the aligned direction.

Preferably aligning the blended conjugated polymers comprises blade coating the blended conjugated polymers on the substrate.

Optionally, aligning comprises rubbing, stretching or fibre spinning the blended conjugated polymers.

Preferably doping of a first conjugated polymer and a second conjugated polymer is performed after aligning the polymers.

Preferably blending the first conjugated polymer with the second conjugated polymer comprises mixing a solution comprising the first conjugated polymer with a solution comprising second conjugated polymer.

Preferably doping a first conjugated polymer and a second conjugated polymer with a dopant comprises ion exchange doping, molecular doping, electrochemical doping, solid state diffusion doping, vapor phase doping, mixed solution doping, sequential doping, acid doping. For example, ion exchange doping.

Preferably doping a first conjugated polymer and a second conjugated polymer with a dopant comprises ion exchange doping with a solution where the oxidising agent is in a concentration range of 0.01 to 10 mM, such as 0.05 to 5 mM or 0.1 to 2 mM.

### BRIEF DESCRIPTION OF FIGURES

FIG. 1 shows differential scanning calorimetry (DSC) measurements on undoped films comprising solely the first conjugated polymer, P1, solely the second conjugated polymer, P2, and a blend of both P1 and P2 (see experimental section below for details). The measurements used a cooling rate of 10°/min.

FIG. 2 shows the electrical conductivity of doped blended films as a function of the molar ratio of P2 incorporated into the blend.

FIG. 3 shows the temperature dependent electrical conductivity of doped films comprising solely P1, solely P2 and a blend of both P1 and P2. Symbols represent experimental data, lines are fits to a Kaiser model.

FIG. 4 shows the temperature dependent Seebeck coefficient of doped films comprising solely P1, solely P2 and a blend of both P1 and P2. The inset represents the distribution of Seebeck coefficient values measured on multiple samples at room temperature.

FIG. 5 shows the temperature dependent thermal conductivity of both doped and undoped films comprising solely P1, solely P2 and a blend of both P1 and P2.

FIG. 6 shows the electrical conductivity (grey) and Seebeck coefficient (black) as a function of exposure time to the FeCl₃ dopant at a concentration of 0.33 mM.

FIG. 7 shows the power factor as a function of exposure time to the FeCl₃ dopant at a concentration of 0.33 mM.

FIG. 8 is a graphical representation of an aligned ribbon-phase PBTTT polymer with a single, low molecular weight component (left), and the same material blended with a higher molecular weight component (right).

FIG. 9 shows a comparison of surface morphology and carrier concentration. (a)-(c) shows AFM images and the corresponding Fast Fourier Transform (FFT) images (insets) of aligned and undoped P1, blend and P2 films, respectively. (d)-(f) show the corresponding sulfur 2p XPS spectra of aligned and undoped P1, blend and P2 films, respectively.

FIG. 10 shows a comparison of crystalline order and paracrystallinity of films by GIWAXS: Measurements with X-rays incident along the chain alignment direction (a) P1, (b) Blend, (c) P2 and perpendicular to the chain alignment direction (d) P1, (e) Blend, (f) P2.

FIG. 11 provides values of Q (010) and extracted paracrystallinity of aligned, doped PBTTT for X-rays incident parallel to the chain alignment direction.

FIG. 12 shows crystalline order across individual grain boundaries investigated by 4D-STEM: (a) Annular dark field (ADF) and the electron diffraction images (inset) of P1; (b) Corresponding variance image highlighting the contrast of the ADF image in (a); (c) Fitted chain orientation map of P1; (d) ADF and the electron diffraction images (inset) of a blend film. (e) Corresponding variance image highlighting the contrast of the ADF image in (d); (f) Fitted chain orientation map of the blend films. In the orientation maps only the dominant order is shown.

FIG. 13 shows spectroscopic measurements of films comprising solely P1, solely P2, and a blend of both P1 and P2. a) polarized ultraviolet-visible spectroscopy of undoped films. (b) Polarized ultraviolet-visible spectroscopy of doped films. (c) Photothermal deflection spectroscopy (PDS) of the polymers, (d) Polarized mid-IR spectra of the doped films for incident light polarized parallel and perpendicular to the chain alignment direction. (e) Enlarged figure of the spectra in (d) for incident light polarized perpendicular to the chain alignment.

FIG. 14 shows grain boundary conductivities obtained by Kaiser model fits of the experimental data shown in FIG. 3.

FIG. 15 shows an AFM image of a doped film comprising a blend of two different polymers, PBTTT and PBSTT.

### EXAMPLES

The materials used in the examples were all commercially available, unless otherwise stated. Anhydrous solvents (<20 ppm water) were used unless otherwise stated.

### Average Molecular Weight

The number average molecular weight (Mn) and the weight average molecular weight (Mw) were determined by an Agilent Technologies 1200 series gel permeation chromatography (GPC) instrument running in chlorobenzene at 80 °C, using two PL mixed B columns in series, and calibrated against narrow polydispersity polystyrene standards.

### Polydispersity Index (PDI)

The polydispersity index was calculated by dividing the weight average molecular weight by the number average molecular weight (Mw/Mn).

### Synthesis of PBTTT (poly(2,5-bis(3-alkylthiophene-2-yl)thieno(3,2-b)thiophene)

A first batch of PBTTT (poly(2,5-bis(3-alkylthiophene-2-yl)thieno(3,2-b)thiophene), denoted herein as P1, was synthesized as described in I. McCulloch et al, Nature Materials 5, 328 (2006), the synthesis method of which is incorporated herein by reference. P1 had a number average molecular weight of 35 kDa and a polydispersity index (PDI) of 1.5.

A second batch, of PBTTT, denoted as P2, was purchased from 1-Material Inc. P2 had an number average molecular weight of 65 kDa and a polydispersity index (PDI) of 2.5.

### Formation of Blended PBTTT Films

Solutions of the PBTTT polymers, P1 and P2, were prepared at a concentration of 10 g/L in 1,2-dichlorobenzene. The solutions were then heated at 120 °C for 1 hour. Defined volumes of the two solutions were then mixed depending on the target ratio of P1 and P2 in the final blend. The mixture was then heated at 120 °C for 10 minutes to ensure the two polymers were well mixed/blended.

Chain alignment was performed using a blade coater located in a nitrogen glovebox (MBraun, <1 ppm O₂, <1 ppm H₂O). A PTFE rod was used as the coating blade. 10 μL of the blended polymer solution was injected into the gap between the blade and a glass substrate. Then the temperature-controlled substrate (80 °C) moved at a fixed speed of 110 μm/s underneath the PTFE coating blade. After blade coating, the polymer blend deposited on the substrate was annealed at 270 °C for 20 mins, then allowed to cool down to room temperature naturally while on a hotplate.

Reference films comprising solely P1 and P2 were prepared analogously using polymer solutions comprising only P1 or P2 respectfully.

### Doping of PBTTT Films

The BMP-TFSI solutions were prepared at 1 M concentration in acetonitrile. FeCl₃ solutions were prepared at 10 mM concentration in acetonitrile. The two solutions were combined to provide a 1 mM/100 mM FeCl₃/BMP-TFSI in acetonitrile solution.

Doping was performed on the spin coater by dropping 140 ml of the 1 mM/100 mM FeCl₃/BMP-TFSI in acetonitrile solution onto the pre-prepared films, keeping the solution on the substrates for 100 seconds, then spinning the excess off at 2000 rpm and washing with 1 mL of acetonitrile.

Lower doping levels were achieved by following the same protocol but using 0.33 mM of FeCl₃ and keeping the solution on the substrate for a controlled period of time between 40 and 160 seconds.

### Film Thickness

Film thickness on a substrate was measured by surface profilometry using a Bruker DekTak XT.

### Conductivity Measurements

The thin film conductivity measurements at room temperature were performed using an Agilent 4155B semiconductor parameter analyzer in a nitrogen atmosphere (Belle Technology, <10 ppm O2, <20 ppm H2O). Each device was isolated by scratching off the film outside the active device area before measurement.

### Differential Scanning Calorimetry

Differential Scanning Calorimetry experiments were carried out using a Q2000 DSC manufactured by TA Instruments using a heat flux method to measure heat flow. The instrument was calibrated using an indium standard. Samples were encapsulated in aluminium sample pans and heated from 0 °C to 300 °C at a constant rate of 10 °C/min with a nitrogen purge gas.

### Temperature Dependent Thermoelectric Measurements

Four-point probe conductivity and Seebeck measurements were measured using an on-chip microfabricated device architecture with integrated heaters and calibrated temperature sensors. PBTTT films were patterned into a Hall bar (420 by 105 micrometers) by photolithography and oxygen plasma etching process as described in J. Chang et al, Adv. Funct. Mater. 2010, 20, 2825-283. The temperature dependent electrical conductivity and Seebeck coefficient evaluation were performed in a closed-cycle LakeShore Cryotronics CRX-4K probe station under high vacuum (10⁻⁷ to 10⁻⁶ mbar). A Keithley 2182A nanovoltmeter (for thermovoltage measurements) and a Keithley 2612B source-meter unit (for voltage sourcing and four probe conductivity measurements) were used for electrical measurements. The error analysis was performed following the report in M. Statz et al, Comm. Phy. 2018, 1, 16.

### AFM Measurements

Tapping Mode AFM measurements were performed on an Oxford Instruments Cypher ES Environmental AFM and with an RTESPA-150 probe (resonant frequency 150 kHz, spring constant 0.4 N m-1, Bruker) to characterize the surface morphology of the samples at a scan rate of 0.5 Hz and 512 samples per line. The data were analyzed with Gwyddion 2.63 (open-source software), including the analysis of PBTTT ribbons by fast Fourier transform (FFT).

The measurements to determine the melting points of pristine PBTTT ribbons were performed in an inert atmosphere protected by a continuous flow of dry N₂, with an RTESPA-150 probe at a scan rate of 0.5 Hz and 512 samples per line. The temperature of the samples was controlled by a programmable sample stage (provided by Cypher ES Environmental AFM) and measured simultaneously by an external type-K thermocouple wielded onto the sample. The melting point of the samples were determined by the observation of the dissociation of the ribbon phase.

### XPS Measurements

XPS spectra were collected on a Thermo Scientific Escalab 250xi. The pass energy of 20 eV, step size of 0.1 eV, spot size of 400 μm and 30 scan averaging was used. Data was processed using CasaXPS software, a Shirley background was used in all fits. Sulfur 2p spectra are characterized by a doublet (2p 3/2 and 2p½) with 2:1 area ratio and spin-orbit coupling Δ=1.18 eV3. Error bars were estimated by a Monte Carlo process in CasaXPS.

### GIWAXS Characterization

GIWAXS measurements were performed at Brookhaven National Lab at the 12-ID Soft Matter Interfaces (SMI) beamline of the National Synchrotron Light Source II (NSLS-II) with a beam energy of 16.1 keV. The 2D scattering patterns were collected at an X-ray incidence angle of 0.10° with a Pilatus 900 K-W detector with a pixel size of 172 μm placed at 279 mm from the sample. The sample and detector were enclosed in a vacuum chamber to suppress air scatter. To cover the range of scattering angles desired, the vertically oriented elongated detector was moved horizontally on a fixed arc and images were later visualized in Xi-CAM software and stitched and radially integrated using custom code⁶.

### Electron Microscopy

The PBTTT thin films were probed using scanning electron diffraction (SED), a 4D-STEM technique with a low (<1 mrad) convergence angle. SED data were acquired on a TS Spectra 300 operated at 300 kV with a convergence angle of ca. 0.5 mrad and a diffraction-limited beam diameter of ca. 6 nm. The current was ca. 20 pA, with a frame time of 1 ms, leading to an electron fluence of ca. 140 e⁻/Å². The diffraction patterns for SED were acquired using a single-chip Medipix3 direct electron detector (256 by 256 pixels) and a camera length of 145 mm, leading to a Δs of 0.0094 Å−1 and to a maximum scattering vector of 1.1 Å⁻¹. Additional data were collected under the same conditions at 200 kV.

Prior to the measurements, thin films were deposited by blade coating onto polystyrene sulphonate (PSS) coated substrates, lifted off in water, transferred onto TEM grids and were then annealed into the ribbon phase while on the TEM grids.

### Polarized Photothermal Deflection Spectroscopy

PDS was performed by a tunable light source consisting of a 250-W quartz tungsten halogen lamp coupled with a 250-mm focal length grating monochromator. The monochromatic excitation beam was modulated at 13 Hz. The sub-gap absorption data A(E) were fitted to an exponential trail to extract the Urbach energy E_{μ}.

### Polarized Ultraviolet-Visible Spectroscopy

UV-vis-NIR spectra were collected on a Shimadzu UV-3600i dual beam spectrometer, with the slit width of 3 nm and the data interval of 1 nm. The background spectra from the blank glass were collected separately.

### Results

### Mixing of Polymers

Blended and doped PBTTT films were prepared as described above using various ratios of P1 and P2. These were compared to reference films comprising solely doped P1 or P2. Undoped pure and blended samples were also prepared for reference.

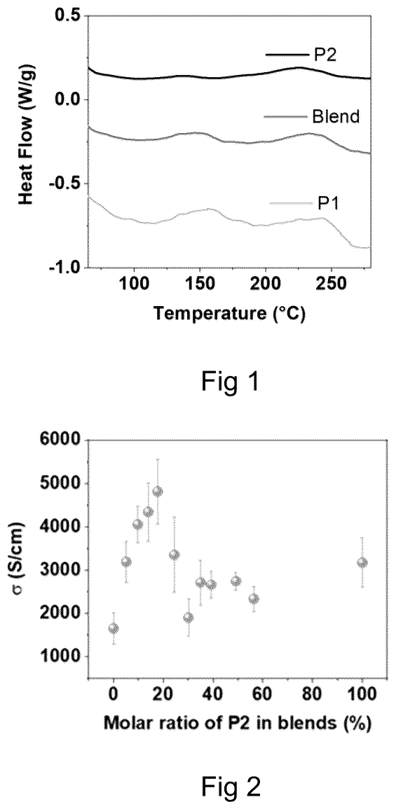

Thin film differential scanning calorimetry (DSC) was used to investigate the thermal transitions of the undoped reference films compared to an undoped blended film, the results of which are shown in FIG. 1. The films formed from solely P1 and P2 both exhibit two exotherms on cooling, but at distinctly different temperatures of 156 °C and 244 °C (P1) and 139 °C and 227 °C (P2). The blended film, which comprised 17.1 mol % P2 (and 82.9 mol % P1), also showed two corresponding transitions, occurring at temperatures of 149 °C and 234 °C. The different DSC transition temperatures were also validated by temperature-dependent AFM measurements. The DSC of the blend was not observed to be a combination of the DSCs of the films formed from solely P1 and P2, but as exhibiting distinct transition temperatures, suggesting that in the blended films there is no phase separation into P1 and P2 domains, but that the two molecular weight pols are intimately mixed within the blend films.

### Improvements in Electrical Conductivity

The electrical conductivity of the doped blended and doped reference films were measured as described above. The evolution of the conductivity of the blended films as a function of the molar ratio of P2 is shown in FIG. 2. Neat P1 and P2 films (0% and 100% P2) showed relatively high electrical conductivities of 1650 S/cm and 3170 S/cm, respectively. However, surprisingly, many of the blended films performed better than the neat P1 and P2 films. Specifically, as the ratio of P2 in the blend films increased from 0%, the electrical conductivity was seen to increase to a peak value of 4810 S/cm at a composition containing 17.1mol % of P2. This maximum electrical conductivity is more than 2.5 times the conductivity of the film formed from doped neat P1. As the P2 content further increases the conductivity initially decreased and then remained at a roughly constant value for the blends with P2 concentrations of ≈35 mol % or more.

All further experimental data shown is for optimum blend composition comprising 17.1 mol % of P2.

### Improvements in Thermoelectric Properties

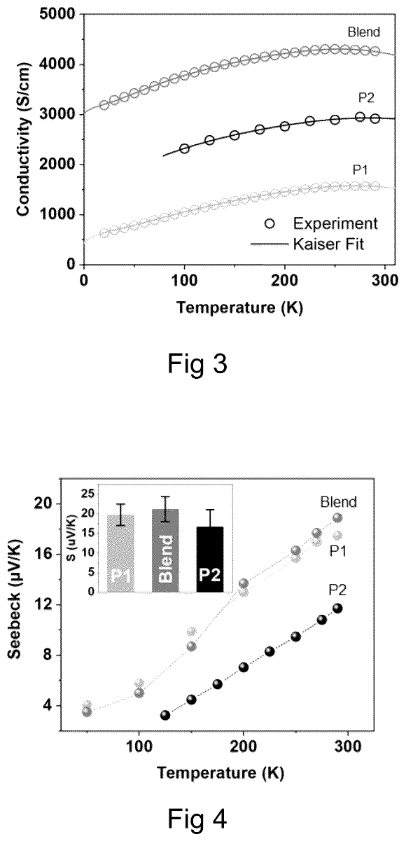

FIG. 3 shows the temperature dependent electrical conductivity of the doped P1 and P2 reference films compared to a doped blended film comprising 17.1 mol % of P2 (and 82.9 mol % P1). In all three films, the conductivity shows a broadly similar temperature dependence typical for high conductivity PBTTT with a flattening or even decrease above 250K. The blended film however shows a significantly improved electrical conductivity compared to the reference films over the entire temperature range.

FIG. 4 shows that the Seebeck coefficient of all the doped films. The Seebeck coefficient varies linearly with temperature, in good agreement with the Mott formula for metals and previous measurements on ion exchange doped PBTTT. The Seebeck coefficient for the blended film is consistently higher than neat P2 and is comparable to neat P1.

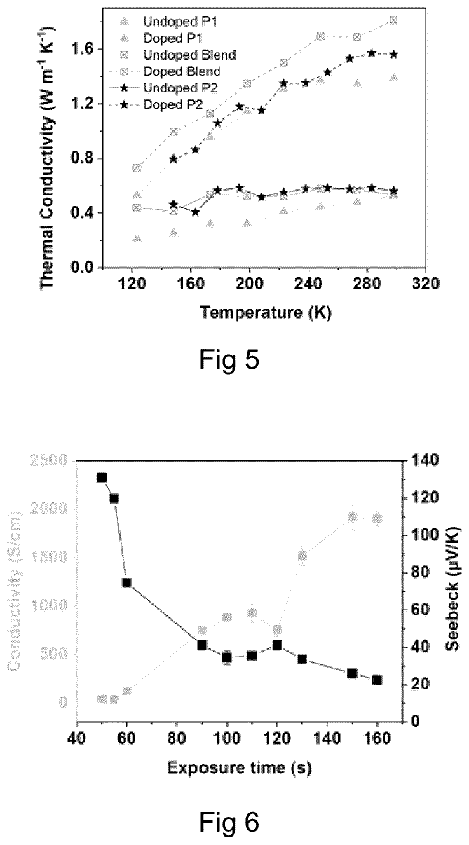

FIG. 5 shows the thermal conductivity of the doped P1 and P2 reference films compared to a doped blended film comprising 17.1 mol % of P2 (and 82.9 mol % P1), along with analogous undoped films. As shown in the figure, the doped samples all exhibit significantly higher thermal conductivity than the undoped samples, which reflects the contribution Ke from the heat carried by introduced charge carriers. The doped blended film shows the highest thermal conductivity over the entire temperature range. However, surprisingly, the increase in thermal conductivity is not as large as would have been expected from the Wiedemann-Franz relationship for the increase in electrical conductivity.

As a result, the doped blended film can be seen to show significant improvements in electrical conductivity compared to the doped unblended reference films, while showing a comparable Seebeck coefficient and relatively small increases in the thermal conductivity. This improved electrical conductivity without the proportional increase in thermal conductivity provides improvements in the figure-of-merit for thermoelectric performance (ZT) as defined according to the equation 1 above.

Put simply, the blended film can be considered to have improved thermoelectric performance (higher ZT) compared to the reference materials. It is unexpected that the blending of the polymers would result in this improved performance and in particular the beneficial increase electrical conductivity while not significantly impacting the other factors, for example, also resulting in a significant increase in thermal conductivity.

### Optimisation of Doping Concentration

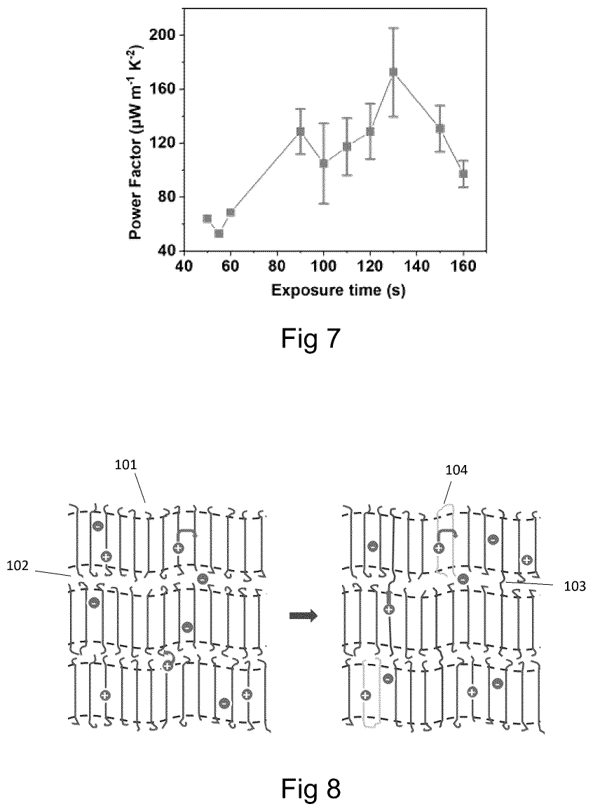

To investigate the blends as a function of doping concentration, the films were exposed to lower concentrations of FeCl₃ for set exposure periods as described in the method section above. As can be seen in FIG. 6 electrical conductivity of blend films was found to increase with exposure time while the Seebeck coefficient decreases. A maximum power factor of 173 μW m⁻¹ K⁻² was reached at the exposure time of 130 s (FIG. 7). This represents a relatively high power factor for this particular polymer. From the measurements, the figure-of-merit for thermoelectric performance, ZT is estimated to be on the order of 0.04-0.05. While this is relatively low compared to some conjugated polymers used for thermoelectric materials, it represents a clear improvement over the reference materials thereby validating the overall approach.

### Proposed Mechanism

Without wishing to be bound by theory, the improved performance, in particular the increase in conductivity of the doped blended films over the reference doped neat P1 or P2 films, is believed to occur because the presence of the higher MW polymer, in a blend with the lower MW polymer, increases the concentration of tie chains that are long enough to bridge between the crystalline ribbons. It is believed that these tie chains facilitate the transport of charges between the crystalline domains (in this case crystalline ribbons). This is shown schematically in FIG. 8. On the left is a representation of P1 films comprising discrete crystalline domains (101) of aligned polymers separated by amorphous regions (102) with no, or at least a very limited number, of connections between the domains (i.e. minimal tie chains). On the right is a representation of a blended film comprising both P1 and P2. The blended structure can be seen to comprise a number of P2 polymers that span the crystalline domains (103) as well as some which fold over and remain within the discrete crystalline domain (104). The presence of the P2 polymer that spans the crystalline domains (103) is thought to allow for improved charge transport between the crystalline domains.

### Evidence for Tie-Chains

It is difficult to directly observe tie chains using any microstructural measurement. A series of structural and spectroscopic measurements were therefore used to probe any differences in the microstructure of the blended and reference polymer films that could potentially provide alternative explanations for the observed behaviour.

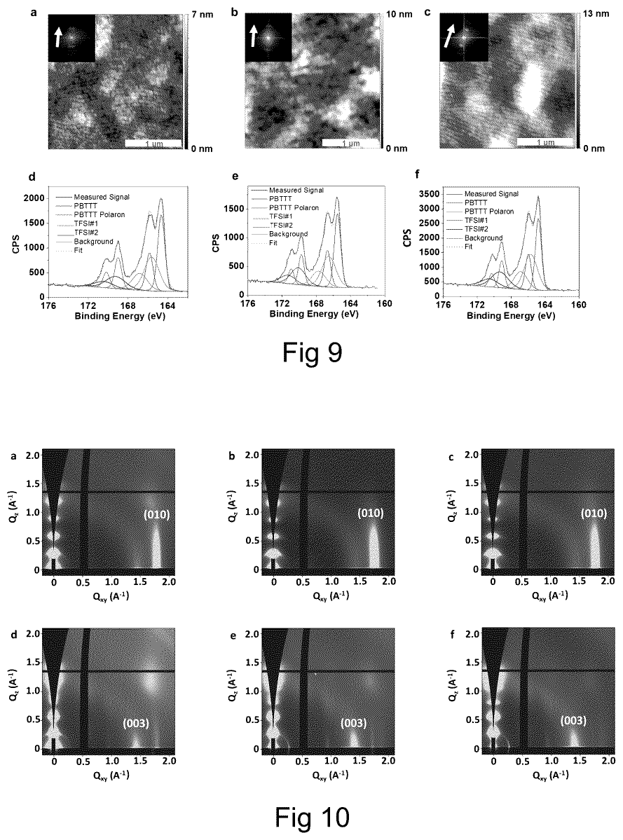

Atomic force microscopy (AFM) was used to probe the morphology and revealed clear and uniform ribbon formation in the undoped P1 and P2 films as well as the updoped blended film comprising 17.1 mol % P2 (FIGS. 9a, 9c and 9b respectively). The ribbons can be seen to be aligned preferentially perpendicular to the blade coating direction, shown by the two well-defined, off-centered peaks corresponding to the ribbon periodicity in the Fourier transform of the AFM images (insets). The white arrows indicate the blade coating direction, i.e., the direction of chain alignment. Statistical analysis of the ribbon widths averaged over three different samples and scan areas of each polymer (FIG. 9a-c) revealed similar periodicity of 68.9±0.4 nm (P1), 71.8±0.1 nm (blends), and 68.9±0.4 nm (P2) despite the fact that P2 has almost twice the MW of P1. This suggests that the polymer chains in P1 films are close to chain extended (i.e. that the chains are predominantly straight and contain minimal folding), while in P2 films the majority of chains contain hairpin chainfolds (indicated in FIG. 8), such that they exhibit similar ribbon width than P1 films. The small, but statistically significant increase in the ribbon width in blend film, compared to both P1 and P2 films, suggests that the incorporation of the higher molecular weight chains leads to a small lengthening of the chain extension in the ribbons which is consistent with the incorporation of tie chains that are likely to lead to a straightening of the chains and chain ends in the grain boundary regions.

To quantify the doping concentrations, X-ray photoemission spectroscopy (XPS) was used. Both TFSI and PBTTT contain sulfur atoms with a clearly resolved chemical shift, which allows quantifying the molar ratio of TFSI to PBTTT from peak fitting of the S 2p signal (FIG. 9d-f). Before XPS measurements, the surface of the films was washed in acetonitrile to eliminate any residues on the surface. For the peak fitting, separate 2p doublet components for each of neutral PBTTT chain segments and PBTTT radical cations were used along with separate components for the two sulfur atoms on TFSI. The calculated molar doping ratio was around one ion per monomer for all 3 samples (doped P1, doped blend and doped P2 films), with only minor differences of 8.5×10²⁰ cm⁻³ (blend), 8.3×10²⁰ cm⁻³ (P2) and 7.6×10²⁰ cm⁻³ (P1), which are not considered statistically significant. As a result, there is there is minimal change to the carrier concentration which might otherwise dominate the transport properties.

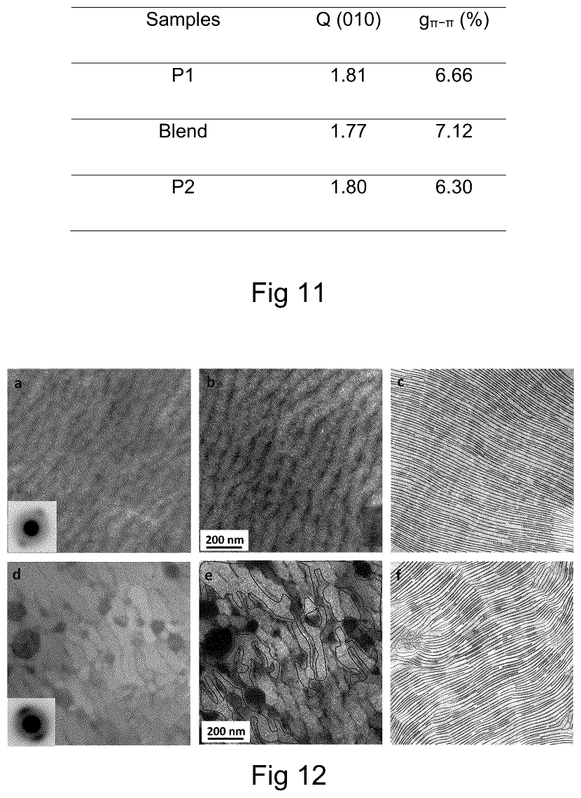

Grazing incidence wide-angle X-ray scattering (GIWAXS) was used to compare the crystalline order of the three films (doped P1, doped blend and doped P2 films). For X-rays incident along the blade-coating direction a strong (010), IT-TT stacking diffraction and only a weak (003) backbone diffraction peak were observed in-plane in all three films (FIG. 10a-c), while for X-rays incident perpendicular to the blade coating direction the (003) backbone is much stronger and the π-π stacking peak is weak (FIG. 10d-f). This indicates that the blended films exhibit a similarly high in-plane chain alignment as the neat films. The paracrystallinities gπ-_{π} for the π-π stacking (FIG. 11) were extratced. All three films exhibit very small g_{π-π} values between 6.3% and 7.1% in their doped state (FIG. 11) with only minor differences between the three samples reflecting the high degree of structural order in the doped ribbon phase films. These small differences in g_{π-π} are insufficient to account for the strong conductivity increase observed upon blending. Paracrystallinity values were also extracted from the (003) backbone diffraction and only a minor reduction in paracrystallinity was observed in P1 compared to P2 and the blends.

4-Dimensional Scanning Transmission Electron Microscopy (4D-STEM) imaging was used to acquire diffraction patterns of individual ribbons and of the grain boundaries between them. The local diffraction patterns (inset of FIG. 12a,d) provide evidence for clear chain alignment with strongly anisotropic π-π stacking and backbone diffractions. In the annular dark field (ADF) images of both P1 (FIG. 12a,b) and blend film (FIG. 12d,e) the ribbon structure is clearly visible, the ribbon width is extracted to have similar value of around 70 nm than in the AFM images. Interestingly, in the local diffraction patterns strong interchain ordering and π-π stacking diffractions at all points crossing from one ribbon to the next was observed, with only a relatively small reduction in intensity in the centre of the grain boundary. The grain boundaries in the blend films appear particularly narrow in the ADF images and were estimated to have a width less than 5 nm. Without wishing to be bound by theory, this suggests that even in the grain boundaries pronounced chain alignment is present. Exact values for the grain boundary width are uncertain due to the finite probe size necessary to have sufficient diffraction resolution. The grain boundary regions in P1 were found to be slightly wider (2.0 nm) than in the blend films. This could be a direct manifestation of tie chains in the blended film leading to a straightening of the polymer chains in the grain boundary regions. In the ADF images regions where the grain boundary contrast disappeared were also detected, i.e. where adjacent ribbons appeared to merge. These are highlighted in FIG. 12e. It appeared that these were more prominent in blend films than in P1 films, in the latter these were essentially absent. Both observations are interpreted as a manifestation of tie chain incorporation and could be directly related to the conductivity behaviour, i.e., narrower grain boundaries are likely to result in faster ribbon-to-ribbon transport and higher conductivity.

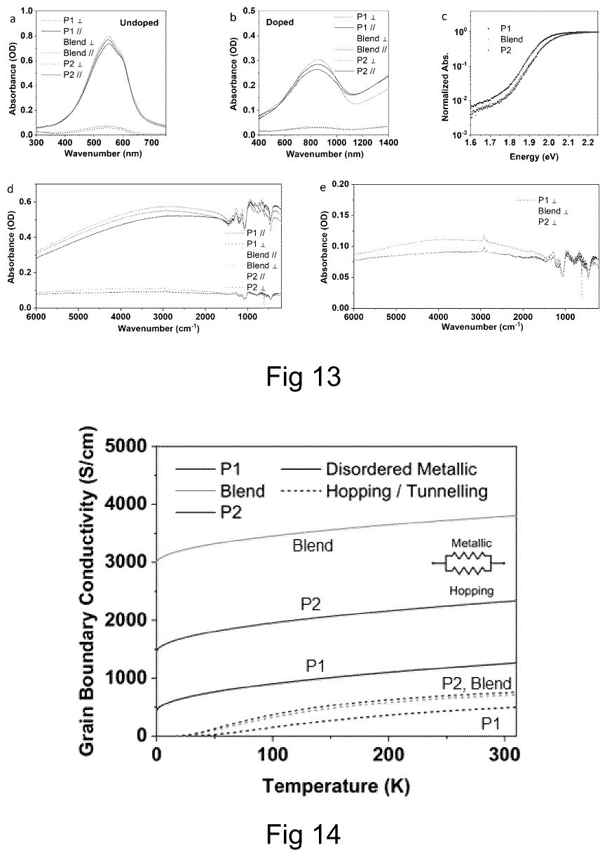

Spectroscopic characterization of the films was also conducted. Polarized ultraviolet-visible (UV-VIS) spectroscopy was used to quantify the degree of chain alignment through the dichroic ratio R=A_{∥ ∥}/A_{⊥}, where A_{∥ ∥} and A_{⊥} represent the peak absorbance at either the 0-0 or 0-1 vibrational peak. The dichroic ratio reached a value of 12.7 for undoped blend films at the neutral π-π* absorption band of 553.1 nm (FIGS. 13a) and 8.9 for doped blends at the polaron-induced absorption band at 875.0 nm (FIG. 13b). Both transitions are known to be polarized along the polymer chains axis and the dichroic ratio provides therefore a quantitative measure of overall chain alignment. Very similar dichroic ratios were also observed in films comprising soley P1 or P2, which demonstrates that high and comparable degree of chain alignment was achieved in the reference films compared to the blended films.

To compare the degree of energetic disorder photothermal deflection spectroscopy (PDS) was carried out on the undoped films (FIG. 13c), which provides a bulk-sensitive probe of the sub-bandgap tail of the excitonic joint density of states and allows extracting the Urbach energy Eₘ from an exponential fit in the sub-bandgap region. Films comprising solely P1 exhibited a slightly lower Eₘ of 50.3 meV than Films comprising solely P2 (51.6 meV) and the blend (51.1 meV). This could indicate higher crystalline order with fewer torsional defects in P1, which is consistent with the DSC, although it is too small an effect to be reflected in the GIWAXS. In fact, the differences in Eₘ are close to the measurement accuracy of PDS. More convincing evidence for a slightly higher degree of crystalline order in P1 may be the observation of a slight lowering of the Eₘ extracted from power law fits of the optical absorption.

Polarized Fourier-transform infrared (FTIR) spectroscopy was used on doped films to measure the polaron-induced absorption in the mid-IR which provide a sensitive probe of the degree of polaron delocalization. Two peaks are typically observed that are referred to as the B peak around 3500-2500 cm⁻¹ and the A peak around 1000 cm⁻¹. A redshift of the B peak and a more intense A peak are signatures of a more pronounced polaron delocalization along the chains and in the interchain direction. The spectra taken with the polarizer along the blade coating direction (FIG. 13d), which are sensitive mainly to the polarons sitting on the highly aligned chains in the crystalline domains, indicate that polarons in the crystalline domains of P1 are slightly more delocalized than those in P2 and blend films, while P2 and blends films exhibit similar polaron delocalisation. This could indicate a lower degree of torsional defects and longer conjugation length in the crystalline domains of P1, which is consistent with the DSC and PDS. When the polarizer is aligned perpendicular to the blade coating direction, the spectra probe preferentially polarons sitting in the less well aligned grain boundary regions (FIG. 5e). These are clearly more localized than those in the crystalline regions, which is consistent with the more disordered chain conformation expected in the grain boundaries. Overall, the spectroscopic characterization shows that although there may well be subtle differences in the crystalline order of the three samples, with P1 exhibiting longer conjugation lengths and more delocalized polarons, these cannot be responsible for the observed conductivity behavior, as they would imply that P1 should exhibit the highest conductivity.

Finally, the electrical conductivity data was fit using a heterogeneous transport model by Kaiser and Graham. The fits indicate that, for all samples and temperatures, grain boundary resistance is at least an order of magnitude greater than intragrain metallic transport and therefore that grain boundaries (where tie-chains would be present) strongly limit conductivity. FIG. 14 shows the conductivity of the two parallel grain boundary conduction pathways, hopping/tunnelling (dashed lines) and disordered metallic (solid lines).

Based on the above evidence, and without wishing to be bound by theory, it appears likely that the improvements is conductivity over films comprising solely P1 occurs due to tie chain incorporation. In P1 films transport is limited by the absence (or low concentration) of tie chains across the grain boundaries, while in blend films the tie chains facilitate the transport across the grain boundaries.

Regarding improvements over P2, without wishing to be bound by theory, it is believed that the high concentration of hairpin chain folds that is present in the P2 films could increase the degree of structural and energetic disorder in the grain boundaries and could limit the ability of the polymer chains to become incorporated as tie chains.

In contrast, in the blend films there are likely to be fewer chain folds and the longer chains are likely to find it easier to remain more chain extended and cross over into the next crystalline domains.

### Mixing of Two Different Polymers

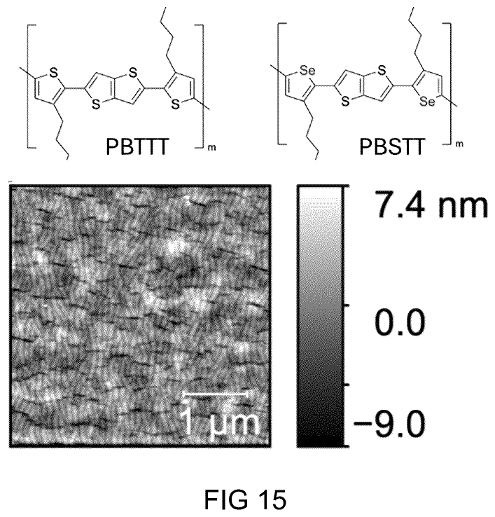

FIG. 15 shows an AFM image that demonstrates that ribbon formation can also be achieved using a blend of two different polymers that have a similar electronic structure. In particular, FIG. 15 shows an example of a blend in which the second conjugated polymer (i.e. polymer with the high molecular weight), is poly((2,5-bis (3-alkylselenophen-2-yl)thieno (3,2-b)thiophene) (PBSTT) and the first conjugated polymer (i.e. the polymer with the smaller molecular weight) is poly(2,5-bis (3-alkylthiophen-2-yl)thieno (3,2-b)thiophene) (PBTTT). The substitution of some of the thiophene atoms with selenium atoms leads to a subtle tuning of the energy levels and of the electronic structure between the two polymers. Selenophene is considered to be more electron donating than thiophene and PBSTT is therefore expected to have a slightly lower ionisation potential that PBTTT. However, the difference is small, typically less than 100 meV, and is also affected by solid-state effects, such as intermolecular interactions.

Another method for achieving the desired tuning of the energy levels of the two polymers could be to attach different electron-withdrawing or electron-donating groups to the polymer backbone, such as replacing some of the backbone protons with electron-withdrawing fluorine atoms (which tend to raise the ionisation potential) or modifying the alkyl side chains, preferably the segment directly attached to the backbone, by replacing some or all of the CH₂/CH₃ units with more electron withdrawing CF₂/CF₃ units or more electron donating ethylene glycol units, while preferably retaining the same side chain length. It will be appreciated that when designing such modifications of the side chains or the backbone care should be taken to retain similar solubility characteristics for the two polymers.

In the choice of the two polymers it is important that the polymer chain conformation and molecular shape remain sufficiently similar to each other such that it becomes possible for the blend of the two polymers to form a common ribbon phase, as seen in the AFM image of FIG. 15. In the system of FIG. 15, 20 mol % of the selenophene-substituted polymer (PBSTT) with a C₁₀H₂₁ alkyl chain length and a molecular weight of Mn=36.9 kDa was used together with 80 mol % of the PBTTT polymer with a C₁₂H₂₅ alkyl chain and a molecular weight of 7.6 kDa. It was found that the 20% blend of PBSTT in PBTTT exhibited a high conductivity of 3000 S/cm, which was more than 20% higher than that of the neat PBTTT film. It is likely that this can be further optimised through the choice of different alkyl chains. For example, the same alkyl chain length could be used for both polymers in order to minimize disorder and incompatibility in structure when blending in the second polymer. It is in fact remarkable that despite this structural difference it was possible for the two polymers to form a common ribbon phase and for the blend to exhibit a higher conductivity than the neat polymer. This demonstrates the robustness of the approach and suggests that there might be significant scope for chemical modification of the second polymer, while retaining the compatibility of the two polymers to form ribbon phases.

### REFERENCES

[1] (a) O. Zapata-Arteaga, S. Marina, J. Martin, J. S. Reparaz,* and M. Campoy-Quiles*, ACS Energy Lett. 2020, 5, 2972-2978; (b) S. Wang, G. Zuo, J. Kim, H. Sirringhaus, Progress in Polymer Science 2022, 129, 101548.
[2] M. G. Kanatzidis*, Nat. Mater. 2022, 21, 503-513.
[3] (a) Y. Huang, D. H. Lukito Tjhe, X. Huang, I. McCulloch, and H. Sirringhaus, Appl. Phys. Lett. 2021, 119; (b) V. Vijayakumar, V. Untilova, M. Bahri, L. Herrmann, L. Biniek,* N. Leclerc,* and M. Brinkmann*, Adv. Energy Mater. 2019, 9, 1900266; (c) G. Giri, J. Reinspach, D.A. Fischer, L. J. Richter, J. Xu, S. Benight, A. Ayzner, M. He, L. Fang, G. Xue, M. F. Toney, and Z. Bao*, Chem. Mater. 2015, 27, 2350-2359.
[4] (a) M. Xiao, S. B. Lee, L. M. A. Perdigão, A. Luci, D. A. Warr, S. P. Senanayak, M. Nikolka, M. Statz, Y. Wu, A. Sadhanala, S. Schott, R. Carey, Q. Wang, M. Lee, C. Kim, A. Onwubiko, C. Jellett, H. Liao, W. Yue, K. Cho, G. Costantini, I. McCulloch, and H. Sirringhaus*, Adv. Mater. 2020, 32, 2000063; (b) L. Shaw, Y. Diao, J. A. Reinspach, J. W. F. To, M. F. Toney, R. T. Weitz, and Z. Bao*, ACS Appl. Mater. Interfaces 2016, 8, 9285-9296; (c) L. Biniek, T. Heiser, R. Bechara, and M. Brinkmann*, Macromolecules 2013, 46, 4014-4023.
[5] T. Hallam, N. Zhao, I. Nandhakumar, M. Kemerink, M. Heeney, I. McCulloch, and H. Sirringhaus*, Phy. Rew. Lett. 2009, 103, 256803.
[6] R. J. Pandolfi, D. B. Allan, E. Arenholz, L. Barroso-luque, S. I. Campbell, T. A. Caswell, A. Blair, F. de Carlo, S. Fackler, A. P. Fournier, G. Freychet, M. Fukuto, R. J. Kline, R. Li, C. Liman, S. Marchesini. J. Synchrotron Radiat. 2018, 25, 1261-1270

1. A semi-crystalline polymeric material comprising:
a first conjugated polymer;
a second conjugated polymer blended with the first conjugated polymer; and
a dopant;
wherein the second conjugated polymer has a number average molecular weight which is 25% greater or more than the number average molecular weight of the first conjugated polymer.

2. A semi-crystalline polymeric material according to claim 1, wherein the first and second conjugated polymer are aligned in a single direction.

3. The semi-crystalline polymeric material according to claim 2, wherein the highest occupied molecular orbit (HOMO) energy level of the second conjugated polymer is within 0.1 eV of the HOMO energy level of the first conjugated polymer; or wherein the lowest unoccupied molecular orbital (LUMO) energy level of the second conjugated polymer is within 0.1 eV of the LUMO energy level of the first conjugated polymer.

4. The semi-crystalline polymeric material according to claim 3, wherein the number average molecular weight of the second conjugated polymer is 50%, or more than the number average molecular weight of the first conjugated polymer.

5. (canceled)

6. (canceled)

7. The semi-crystalline polymeric material according to claim 4, wherein the molar ratio of the second conjugated polymer in a blend of the first conjugated polymer and the second conjugated polymer is less than 50%.

8. The semi-crystalline polymeric material according to claim 7, wherein the molar ratio of the second conjugated polymer in the blend of the first conjugated polymer and the second conjugated polymer is greater than 5%.

9. The semi-crystalline polymeric material according to claim 8, wherein the semi-crystalline polymeric material comprises discrete crystalline domains and wherein a polymer of the first conjugated polymer adopts a substantially straight conformation within the crystalline domains.

10. The semi-crystalline polymeric material according to claim 9, wherein the dopant is selected from a neutral molecular dopant, an ionic dopant, an ion introduced by an ion exchange process, an ion introduced electrochemically, a dopant introducing electrophilic or nucleophilic attack or a dopant inducing proton transfer.

11. The semi-crystalline polymeric material according to claim 10, further comprising a molar doping ratio of 0.01 to 2 charge carriers per monomer.

12. The semi-crystalline polymeric material according to claim 11, wherein the first conjugated polymer and/or the second conjugated polymer is selected from the group consisting of: polythiophenes, polyselenophenes, polyfuranes, polythiazoles, polymers comprising thiophene, polymers comprising thienothiophene, polymers comprising selenophene units, polymers comprising diketopyrrolopyrrole units, polymers comprising thiophene, and polymers comprising fluorinated benzothiadiazole.

13. The semi-crystalline polymeric material according to claim 26. wherein the first conjugated polymer and/or the second conjugated polymer comprises a thiophene unit within the polymeric backbone.

14. The semi-crystalline polymeric material according to claim 13, wherein the first conjugated polymer has a number average molecular weight of at least 15 KDa, and/or wherein the second conjugated polymer has a number average molecular weight of at least 30 KDa.

15.-25. (canceled)

26. The semi-crystalline polymeric material according to claim 12, wherein the first conjugated polymer and the second conjugated polymer differ only by single-atom substitutions in the polymer repeat unit, or in the attachment of electron-withdrawing or electron-donating groups to a polymer backbone, while maintaining a same bonding pattern of the polymer backbone; and/or wherein the first conjugated polymer and the second conjugated polymer comprise a same conjugation system.

27. A thermoelectric material comprising a layer of a semi-crystalline polymeric material comprising:
a first conjugated polymer;
a second conjugated polymer blended with the first conjugated polymer; and
a dopant;
wherein the second conjugated polymer has a number average molecular weight which is 25% greater or more than the number average molecular weight of the first conjugated polymer, wherein the first and second conjugated polymer are aligned in a single direction, and wherein the highest occupied molecular orbit (HOMO) energy level of the second conjugated polymer is within 0.1 eV of the HOMO energy level of the first conjugated polymer.

28. A thermoelectric material comprising a layer of a semi-crystalline polymeric material comprising:
a first conjugated polymer;
a second conjugated polymer blended with the first conjugated polymer; and
a dopant;
wherein the second conjugated polymer has a number average molecular weight which is 25% greater or more than the number average molecular weight of the first conjugated polymer, wherein the first and second conjugated polymer are aligned in a single direction, and wherein the lowest unoccupied molecular orbit (LUMO) energy level of the second conjugated polymer is within 0.1 eV of the LUMO energy level of the first conjugated polymer.
